(19) United States
(12) Patent Application Publication
(10) Pub. No.: US 2024/0422912 A1
(43) Pub. Date: Dec. 19, 2024

(54) ELECTRONIC DEVICE

(71) Applicant: PanelSemi Corporation, New Taipei City (TW)

(72) Inventor: Sheng-Ping CHIANG, New Taipei City (TW)

(21) Appl. No.: 18/743,743

(22) Filed: Jun. 14, 2024

Related U.S. Application Data
(60) Provisional application No. 63/508,736, filed on Jun. 16, 2023.

(51) Int. Cl. H05K 1/14; H05K 1/11; H05K 1/18

(52) U.S. Cl. CPC H05K 1/144; H05K 1/115; H05K 1/185; H05K 2201/042; H05K 2201/09227

(57) ABSTRACT

An electronic device is provided. The electronic device includes a first substrate, a second substrate and a third substrate. The first substrate has a first trace layer, which defines a first trace width. The second substrate has a second trace layer and stacked under the first substrate. The second substrate defines a first surface connecting to the first substrate and a second surface opposite to the first surface. The second trace layer is formed on either or both of the first and second surfaces and defines a second trace width. The third substrate is stacked under the second substrate and connected to the second surface. The third substrate has a third trace layer, which defines a third trace width. At least a partial of the second trace width is no greater than both of the first trace width and the third trace width.

### CROSS REFERENCE TO RELATED APPLICATIONS

This Non-provisional application which claims priority under 35 U.S.C. § 119 (a) on Patent Application No(s). 63/508,736 filed in United States of America on Jun. 16, 2023, the entire contents of which are hereby incorporated by reference.

### BACKGROUND

### Technology Field

The disclosure relates to an electronic device and specifically refer to an electronic device formed by multi-layered substrates especially a multi-layered substrate with fine circuit inside thereof.

### Description of Related Art

A multi-layer circuit board refers to a circuit board having multiple circuit layers. It has the advantages of high assembly density, improved signal transmission rate and better control of electromagnetic interference. However, the multi-layer circuit board is difficult to be manufactured, and it is not easy to arrange various electronic elements between the multiple circuit layers. Therefore, the application of the multi-layer circuit board is still limited.

### SUMMARY

One or more exemplary embodiments of this disclosure are to provide an electronic device, beneficial of flexibility of combination for substrate(s) and component(s).

This disclosure provides an electronic device including a first substrate, a second substrate, and a third substrate stacked sequentially. Each substrate has its own trace layer provided with its own trace width, and the second trace width of the second trace layer on the second substrate is no greater than both of the first/third trace width of the first/third trace layer respectively on the first substrate and the third substrate.

In addition, this disclosure provides an electronic device has a similar structure above mentioned. In this case, each substrate defines its own trace layer provided with its own line space, and the second line space of the second trace layer on the second substrate is no greater than both of the first/third line space of the first/third trace layer respectively on the first substrate and the third substrate.

Furthermore, this disclosure also provides an electronic device has a similar structure above mentioned. In this case, each substrate defines its own trace layer provided with its own trade width and line space. The second trace width and the second line space of the second trace layer on the second substrate is no greater than both of the first/third trace width and the first/third line space of the first/third trace layer respectively on the first substrate and the third substrate.

In one embodiment, the second substrate is a resilient substrate.

In one embodiment, the second substrate comprises at least one redistribution wiring structure, and the redistribution wiring structure comprises one trace layer or more stacked trace layers.

In one embodiment, the second substrate defines a thickness no greater than 150 μm.

In one embodiment, the second substrate defines a thickness no greater than 100 μm.

In one embodiment, the second substrate defines a thickness no greater than 50 μm.

In one embodiment, a partial of the second trace layer defines a thickness no greater than 15 μm.

In one embodiment, a partial of the second trace layer defines a thickness no greater than 10 μm.

In one embodiment, a partial of the second trace layer defines a thickness no greater than 5 μm.

In one embodiment, the second trace layer defines a bonding region and a non-bonding region, and the partial of the second trace layer is within the non-bonding region.

In one embodiment, the electronic device further includes a plurality of components arranged on either or both of the first surface and the second surface of the second substrate, and electrically connected to the second trace layer.

In one embodiment, at least one of the components is an active element.

In one embodiment, the active element is a thin film transistor.

In one embodiment, the electronic device further includes a plurality of conductive elements arranged between at least two of the first substrate, the second substrate, and the third substrate.

In one embodiment, the conductive element is met through conductive via or wiring.

In one embodiment, the electronic device further includes an adhesion material connecting adjacent two of the first substrate, the second substrate, and the third substrate.

In one embodiment, a measured area of the second substrate is no less than either or both of the first substrate and third substrate.

In one embodiment, the electronic device comprises a plurality of second substrates between the first substrate and the third substrate.

In one embodiment, either or both of the first substrate and the third substrate are ceramic substrates.

In one embodiment, at least one of the first substrate, the second substrate, and the third substrate is a multi-layered substrate or a composite substrate.

In one embodiment, at least one of the first substrate, the second substrate, and the third substrate is a single-layered substrate.

Accordingly, the present disclosure provides an electronic device having at least three substrates, in which a fine-line circuit and at least one component are arranged inside the electronic device.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing an electronic device according to an embodiment of this disclosure; and

FIG. 2 is a schematic diagram showing an electronic device according to another embodiment of this disclosure.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

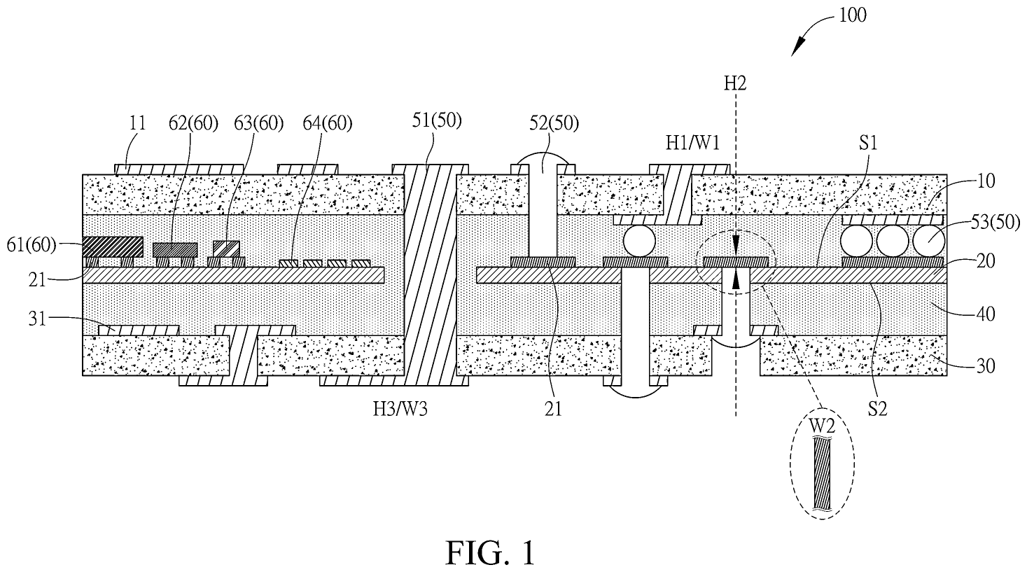

An electronic device 100, referred as an embodiment in FIG. 1, includes a first substrate 10, a second substrate 20, and a third substrate 30 which are sequentially stacked. Each substrate defines its own trace layer provided with its own trace width and its own line space. Either or both of the trace width and the line space of the second trace layer on the second substrate 20 is no greater than either or both of the trace width and the line space of both the first trace layer and the third trace layer. Furthermore, at least two of these three substrates are electrically connected.

In detail, the first substrate 10 has a first trace layer 11, and the first trace layer 11 defines a first trace width W1, a first line space and a first thickness H1. In some cases, the first trace layer 11 could be formed on a surface of the first substrate 10 facing to the second substrate 20.

The second substrate 20 is stacked under one surface of the first substrate 10 and defines a first surface S1 and a second surface S2 opposite to the first surface S1, and the first surface S1 faces to the surface of the first substrate 10. The second substrate 20 has a second trace layer 21 formed on either or both of the first surface S1 and the second surface S2 thereof. The second trace layer 21 defines a second trace width W2, a second line space and a second thickness H2.

The third substrate 30 is stacked under the second substrate 20 and faces to the second surface S2 of the second substrate 20 by one surface thereof. The third substrate 30 has a third trace layer 31, and the third trace layer 31 defines a third trace width W3, a third line space and a third thickness H3. In some cases, the third trace layer 31 could be formed on a surface of the third substrate 30 facing to the second substrate 20.

In some cases, the second trace layer 21 has an unequal trace width. In some cases, the second trace width W2 has a minimum trace width no greater than 15 μm; in some cases, the second trace width W2 has a minimum trace width no greater than 10 μm; in some cases, the second trace width W2 has a minimum trace width no greater than 5 μm; in some cases, the second trace width W2 has a minimum trace width no greater than 2 μm; and in some cases, the second trace width W2 has a minimum trace width no greater than 1 μm.

In some cases, the second trace layer 21 has an unequal line space. In some cases, the second line space has a minimum line space no greater than 15 μm; in some cases, the second line space has a minimum line space no greater than 10 μm; in some cases, the second line space has a minimum line space no greater than 5 μm; in some cases, the second line space has a minimum line space no greater than 2 μm; and in some cases, the second line space has a minimum line space no greater than 1 μm.

In some cases, either or both of the first substrate 10 and the third substrate 30 is a rigid substrate or a resilient substrate, which can be made of or include Polyester (PET) materials, Polyimide (PI) materials, glass materials, fiberglass materials (adapted for Flame-Retardant substrates), Phenolic resin materials, ceramic materials, metal materials, or the like.

In some cases, the first substrate 10 is a rigid substrate and the third substrate 30 is also a rigid substrate.

In some cases, the second substrate 20 is a resilient substrate, which may be made of or include Polyester (PET) materials, Polyimide (PI) materials, Poly Ethylene Naphthalate (PEN), Liquid Crystalline Polymer (LCP), or the like, or materials other than PI/PET/PEN/LCP but thin enough to be resilient.

In some cases, the first substrate 10 and the third substrate 30 are double-sided-trace-layer printed circuit substrates. In some cases, the second substrate 20 is a single-layered substrate. In some cases, at least one of the first substrate 10, the second substrate 20 and the third substrate 30 is a multi-layered printed circuit substrate.

In some cases, the second substrate 20 defines a thickness no greater than 150 μm; in some cases, the second substrate 20 defines a thickness no greater than 100 μm; in some cases, the thickness of the second substrate 20 is no greater than 50 μm; in some cases, the thickness of the second substrate 20 is no greater than 38 μm; in some cases, the thickness of the second substrate 20 is no greater than 25 μm; and in some cases, the thickness of the second substrate 20 is no greater than 15 μm. To be noted, the thickness of the second substrate 20 described here indicates an equal thickness, an average thickness, a maximum or a minimum thickness, but is not limited thereto.

In some cases, a partial of the thickness H2 of the second trace layer 21 is no greater than 15 μm; in some cases, a partial of the thickness H2 of the second trace layer 21 is no greater than 10 μm; furthermore, in some cases, a partial of the thickness H2 of the second trace layer 21 is no greater than 5 μm. To be noted, the thickness H2 of the second trace layer 21 described here could be an equal thickness, an average thickness, a maximum thickness or a minimum thickness, but is not limited thereto.

In some cases, an adhesion layer or adhesion layers 40 is/are further arranged between two adjacent ones of the first substrate 10, the second substrate 20, and the third substrate 30 for combination. The adhesion layer(s) 40 sandwiched between the first substrate 10 and the second substrate 20, or between the second substrate 20 and the third substrate 30 may be selected as the same materials or not. The adhesion layer(s) 40 sandwiched between the first substrate 10 and the second substrate 20 and between the second substrate 20 and the third substrate 30 may joining with each other or not.

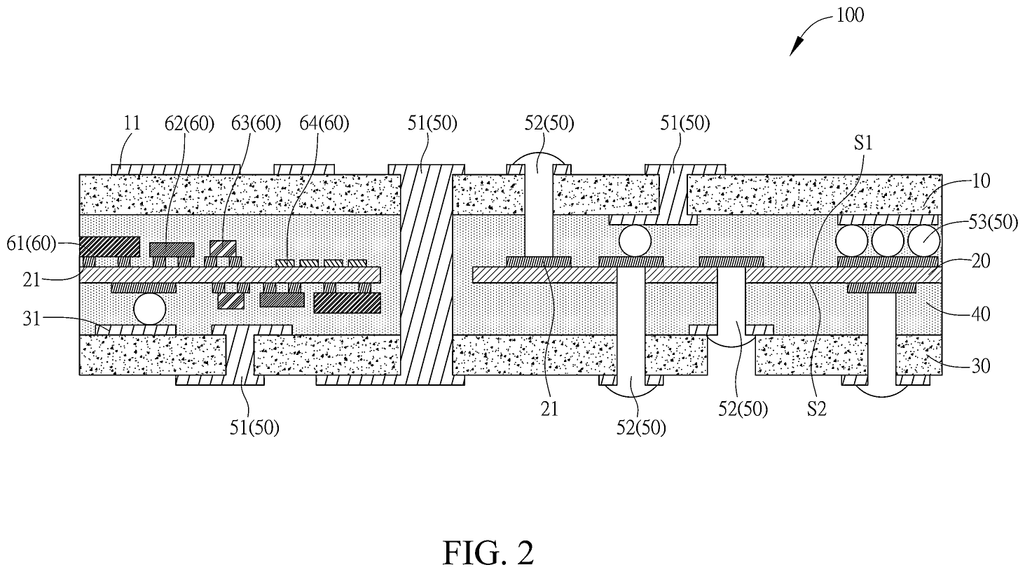

In some cases, there are a plurality of conductive elements 50 arranged between either two of the first substrate 10, the second substrate 20, and the third substrate 30. The conductive element(s) 50 is met through conductive via or wiring, which is not limited thereto. The conductive elements 50 can be met in various approaches as elements 51, 52 and 53 shown in FIG. 1 and FIG. 2. However, the configurations of the conductive elements 50 are not limited thereto, and the conductive elements 50 are not necessary to be the same. The conductive elements 50 are used for electrical connection of at least two of the first substrate 10, the second substrate 20 and the third substrate 30.

To be noted, a plurality of components 60 is further provided to the electronic device 100. The plurality of components 60 are arranged on either or both of the first surface S1 and the second surface S2 of the second substrate 20 as shown in FIG. 1 and FIG. 2. In some cases, at least some of the components 60 are active elements or passive elements.

In some cases, the second trace layer 21 defines a bonding region and a non-bonding region, in which the bonding region is the region where the component 60 is arranged, and the non-bonding region is the remaining part of the second trace layer 21. A partial of the second trace layer 21 with a thickness no greater than 10 μm is arranged within the non-bonding region, and the thickness H2 of the other partial of the second trace layer 21 arranged within the bonding region is not limited thereto. Furthermore, the thickness H2 of the second trace layer 21 within the bonding region may further include the thickness of a connection pad.

In some cases, the components 60 include active elements, such as mini-scale integrated circuit (IC) or/and microscale IC 61 or thin film transistors 62. The components 60 may further include passive elements 63, 64.

In the case that the second substrate 20 is a fine-line substrate provided with components 60, it would be easy to obtain a high-density interconnector printed circuit board.

In some cases, some of the components 60 are manufactured by a thin film process, and some of the components 60 are individual elements arranged on the second substrate 20.

In the case that the second substrate 20 is a single-layered substrate, it would meet a budgetary cost for the components 60 being set only on one surface of the second substrate 20.

In one case, the second substrate 20 is a resilient substrate and the third substrate 30 is a rigid substrate. The second substrate 20 or the electronic device 100 having the same would be thinner and weight-lighter for the components 60 being arranged only on one surface of the second substrate 20. Thus, the resilient second substrate 20 can be applied onto the rigid third substrate 30, then the components 60 are arranged on one surface of the second substrate 20 opposite to the third substrate 30, and at last, the first substrate 10 is stacked over the components 60 for further electrical connections and on-going processes. In this case, the components 60 is arranged between the first substrate 10 and the second substrate(s) 20.

In another case in which the second substrate 20 is a resilient substrate and the third substrate 30 is a rigid substrate, the resilient second substrate 20 can be applied onto the rigid third substrate 30 after the components 60 are arranged on one surface of the second substrate 20 facing to the third substrate 30. After that, the first substrate 10 is then stacked over on the second substrate 20 for further electrical connections and on-going processes. In this case, the components 60 is arranged between the third substrate 30 and the second substrate(s) 20.

In another case, the resilient second substrate 20 can be applied onto the rigid third substrate 30 after the components 60 are arranged on one surface of the second substrate 20 facing to the third substrate 30, and other components 60 are then arranged on the opposite surface of the second substrate 20. Then the first substrate 10 stacked over on the second substrate 20 for further electrical connections and on-going processes.

In the case where the second substrate 20 is a resilient substrate, and a perpendicular projection area to the second substrate 20 of either of both of the first surface S1 and the second surface S1, is no less than the perpendicular projection area of either or both of the first substrate 10 and the third substrate 30. In addition, a measured area of either of both of the first surface S1 and the second surface S2 of the second substrate 20, is also no less than the measured area of either or both of the first substrate 10 and third substrate 30. In this case, an extension part of the second substrate 20 may serve for arrangement of additional conductive elements 50 or component 60. However, in another case, at least one of the two surfaces of the second substrate 20 has a smaller perpendicular projection area to the second substrate 20 than the perpendicular projection area of either or both of the first substrate 10 and the third substrate 30; or a measured area of either of both of the first surface S1 and the second surface S2 of the second substrate 20 is also less than the measured area of either or both of the first substrate 10 and the third substrate 30.

In some cases, the second substrate 20 comprises at least one redistribution wiring structure, and the redistribution wiring structure comprises one trace layer or more stacked trace layers. Furthermore, an insulation layer is arranges between two adjacent trace layers thereof. In one case, the redistribution wiring structure is formed on an original substrates other than the second substrate 20. In another case, the redistribution wiring structure is formed on the second substrate 20, which means the second substrate 20 can be used as the original substrate of the redistribution wiring structure.

In some cases, the electronic device 100 comprises a plurality of the second substrates between the first substrate and the third substrate. These second substrates 20 can be arranged between the first substrate 10 and the third substrate 30 in a stacked manner. These second substrates 20 can also arranged between the first substrate 10 and the third substrate 30 in a coplanar manner. In addition, these second substrates 20 can be arranged by the two abovementioned manners.

In some cases, the quantity of the first substrate 10 is plural, and at least a partial of the second line width, the second line space, or both of the second trace layer on the second substrate 20 is no greater than the first line width, the first line space, or both of the first trace layer on at least one of these first substrates 10.

In some cases, the quantity of the third substrate 30 is plural, and at least a partial of the second line width, the second line space, or both of the second trace layer on the second substrate 20 is no greater than the third line width, the third line space, or both of the third trace layer on at least one of these third substrates 30.

In some cases, the first substrate 10 and the third substrate 30 are rigid substrates, and the second substrate 20 is a resilient substrate. In addition, either or both of the second trace width and second line space of the second trace layer 21 on the second substrate 20 are no greater than the first/third trace width and the first/third line space of the first/third trace layer 11/31 respectively on the first substrate 10 and the third substrate 30.

In the case that the second substrate 20 is a single-layered and resilient substrate, the electronic device 100 having the second substrate 20 has benefits of high-density interconnection and reduction of production cost.

In one case that the second substrate 20 is a rigid substrate, such as a glass substrate, the electronic device 100 having this second substrate 20 may have larger measured area than an electronic device with substrate made of non-glass material. It is because in the art of manufacturing of TFT-LCD, a great process capability of circuits on a larger glass substrate is established, which can be applied for manufacturing multi-layered printed circuit board as this disclosure.

Accordingly, the present invention provides an electronic device formed by multi-layer substrates especially a multi-layered substrate with fine circuit inside thereof. In addition, different types or different sizes of the electronic elements can be arranged between the multi-layers of this disclosure, which increases the flexible of the application of this disclosure.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a first substrate having a first trace layer, wherein the first trace layer defines a first trace width;
at least one second substrate having a second trace layer and stacked under the first substrate, wherein the second substrate defines a first surface connecting to the first substrate and a second surface opposite to the first surface, and wherein the second trace layer is formed on either or both of the first surface and the second surface of the second substrate and defines a second trace width; and
a third substrate stacked under the second substrate and connected to the second surface of the second substrate, wherein the third substrate has a third trace layer, and wherein the third trace layer defines a third trace width;
wherein at least a partial of the second trace width of the second trace layer is no greater than both of the first trace width of the first trace layer and the third trace width of the third trace layer.

2. The electronic device as claimed in claim 1, wherein the second substrate is a resilient substrate.

3. The electronic device as claimed in claim 1, wherein the second substrate comprises at least one redistribution wiring structure, and the redistribution wiring structure comprises one trace layer or a plurality of stacked trace layers.

4. The electronic device as claimed in claim 3, wherein the redistribution wiring structure is arranged on either or both of the first surface and the second surface of the second substrate.

5. The electronic device as claimed in claim 1, wherein a quantity of the first substrate is plural, and at least a partial of the second line width of the second substrate is no greater than the first line width of at least one of the first substrates.

6. The electronic device as claimed in claim 1, wherein a quantity of the third substrate is plural, and at least a partial of the second line width of the second substrate is no greater than the third line width of at least one of the third substrates.

7. The electronic device as claimed in claim 1, wherein the first trace layer defines a first line space, the second trace layer defines a second line space, and the third trace layer defines a third line space, and wherein at least a partial of the second line space of the second trace layer is no greater than both of the first line space of the first trace layer and the third line space of the third trace layer.

8. The electronic device as claimed in claim 1, wherein the second trace layer defines a bonding region and a non-bonding region, and wherein the partial of the second trace layer is within the non-bonding region.

9. The electronic device as claimed in claim 1, further including a plurality of components arranged on either or both of the first surface and the second surface of the second substrate, and the plurality of components are electrically connected to the second trace layer.

10. The electronic device as claimed in claim 9, wherein at least one of the components is an active element.

11. The electronic device as claimed in claim 1, wherein either or both of the first substrate and the third substrate is a rigid substrate.

12. The electronic device as claimed in claim 1, further including a plurality of conductive elements arranged between at least two of the first substrate, the second substrate, and the third substrate.

13. The electronic device as claimed in claim 12, wherein the conductive element is met through conductive via or wiring.

14. The electronic device as claimed in claim 1, further including an adhesion material connecting adjacent two of the first substrate, the second substrate, and the third substrate.

15. The electronic device as claimed in claim 1, wherein a measured area of the second substrate is no less than either or both of the first substrate and the third substrate.

16. The electronic device as claimed in claim 1, comprising a plurality of the second substrates between the first substrate and the third substrate.

17. The electronic device as claimed in claim 16, wherein the plurality of the second substrates are arranged between the first substrate and the third substrates in a stacked manner, or in a coplanar manner.

18. An electronic device, comprising:
a first substrate having a first trace layer, wherein the first trace layer defines a first line space;
a second substrate having a second trace layer and stacked under the first substrate, wherein the second substrate defines a first surface connecting to the first substrate and a second surface opposite to the first surface, and wherein the second trace layer is formed on either or both of the first surface and the second surface of the second substrate and defines a second line space; and
a third substrate stacked under the second substrate and connected to the second surface of the second substrate, wherein the third substrate has a third trace layer, and wherein the third trace layer defines a third line space;
wherein at least a partial of the second line space of the second trace layer is no greater than both of the first line space of the first trace layer and the third line space of the third trace layer.

19. The electronic device as claimed in claim 18, further including an adhesion material connecting adjacent two of the first substrate, the second substrate, and the third substrate.

20. The electronic device as claimed in claim 18, comprises a plurality of the second substrates between the first substrate and the third substrate.
